(19) United States
(12) Patent Application Publication
(10) Pub. No.: US 2025/0196901 A1
(43) Pub. Date: Jun. 19, 2025

(54) DETECTION METHOD FOR DETECTING A VEHICLE WITHIN AN AREA

(71) Applicant: ALSTOM Holdings, Saint-Ouen-sur-Seine (FR)

(72) Inventors: Andrea PASQUALIS, CAMPI BISENZIO (FI) (IT); Lorenzo POZZI, Carmignano (PO) (IT); Federico CARPINETI, Santa Maria a Monte (PI) (IT); Andrea NANNUCCI, FIRENZE (IT)

(21) Appl. No.: 18/977,638

(22) Filed: Dec. 11, 2024

(30) Foreign Application Priority Data
Dec. 13, 2023 (EP) 23307195.0

(51) Int. Cl. B61L 23/04; G01R 27/26

(52) U.S. Cl. CPC B61L 23/041; G01R 27/2611

(57) ABSTRACT

The detection method uses an inductive loop detection system including: at least one inductive detection loop embedded in the area, a resonation capacitor array configured to detect vehicles by a change in the inductance of at least a loop determined by conductive material of the vehicles. The detection system includes a test inductor with a first switch for connecting the test inductor to the resonation capacitor array in place of the detection loop, the test inductor having a defined and known inductance, so that the effect of the test inductor on a resonance signal of the resonation capacitor array is known and is compared with a reference signal. In case the resonance signal is different from the reference signal, the method includes a recalibrating step for recalibrating the resonation capacitor array.

### INCORPORATION BY REFERENCE TO ANY PRIORITY APPLICATIONS

Any and all applications for which a foreign or domestic priority claim is identified in the Application Data Sheet as filed with the present application are hereby incorporated by reference under 37 CFR 1.57.

### FIELD

The present disclosure relates to a detection method for detecting a vehicle within an area, using an inductive loop detection system.

### BACKGROUND

Preferentially, the area is a railroad crossing. The detection system is intended to detect the presence and/or the passage of vehicles on a well delimited crossing area. Such an application needs a high safety level, ensuring that all vehicles are always detected correctly, in particular before a railway vehicle comes on the crossing.

### SUMMARY

The present disclosure is intended to ensure a Safety Integrity Level 4 (SIL4), which is the highest safety level as defined by the standard IEC 61508. To this end, the present disclosure proposes a very reliable maintenance method, intended to test the inductive loop detection system and to recalibrate it in case of default.

Besides, the present disclosure proposes reaching a SIL4 while keeping a system simple and reliable.

To this end, the present disclosure relates to a detection method for detecting vehicles within an area, using an inductive loop detection system comprising:
at least one inductive detection loop embedded in the area,
a resonation capacitor array intended to detect vehicles thanks to a change in the inductance of at least a loop determined by conductive material of the vehicles,
characterized in that:
the inductive loop detection system comprises at least a test inductor with a first switch for connecting the test inductor to the resonation capacitor array in place of the at least one inductive detection loop, the test inductor having a defined and known inductance, so that the effect of the test inductor on a resonance signal of the resonation capacitor array is known and is compared with a reference signal,
in case the resonance signal is different from the reference signal, the method comprises a recalibrating step for recalibrating the resonation capacitor array.

In a resonant circuit comprising at least one vehicle detection inductive loop connected with a capacitor unit and an optional resistance unit, the amplitude response to a given driving frequency is measured in order to detect the change of the resonant frequency caused by the variation of the inductance of the inductive loop interfering with a vehicle. The setting correctness and the response of the resonant circuit is tested by connecting the test inductor in the circuit, the test inductor having a known inductance.

A non-compliant drift of the resonance signal within a certain frequency band with the inductance introduced by the test inductor indicates that the resonant circuit response is not correct and that steps has to be taken for recalibrating it.

The present disclosure thus proposes a simple way to verify the circuit stability and to recalibrate it in case of default.

A detection method according to the present disclosure may comprise any of the following features, taken alone or in any possible combination:
The area is a crossroad area of a railway.
The resonation capacitor array comprises a main capacitor, and a plurality of additional capacitors in parallel with the main capacitor, each additional capacitor being associated with a respective switch for connecting or disconnecting the corresponding additional capacitor with the resonation capacitor array.
The resonation capacitor array comprises a shunt, in series with the main capacitor.
The inductive detection loops are arranged in parallel to each other, each inductive detection loop being associated with a respective switch, so that the resonation capacitor array can be alternatively or in sequence connected to each of inductive detection loops.
The inductive loops are connected in a galvanic isolated manner to the resonation capacitor array by means of a transformer, preferentially having loop ratio 1 to 1.
The first switch is arranged between the resonation capacitor array and the transformer, and between the resonation capacitor array and the test inductor, so the resonation capacitor array can be connected to the transformer or to the test inductor, and a second switch is arranged between the transformer and the inductive loops, and between the transformer and the test inductor, so the transformer can be connected to the inductive loops, or to the test inductor.
The resonation capacitor array is energized with a Variable Frequency Square Wave signal supplied by a H-bridge controller, by means of an H-bridge.

### BRIEF DESCRIPTION OF THE DRAWINGS

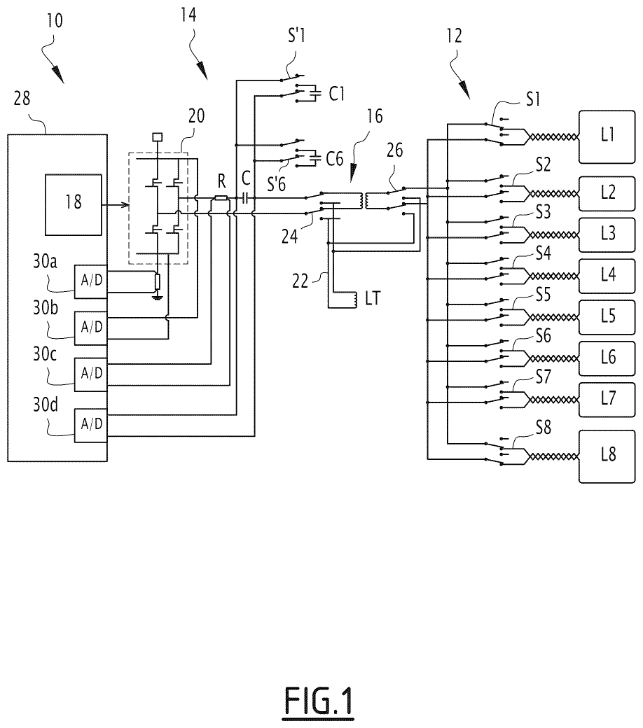

Several aspects and advantages of the present disclosure will be enlightened in the following disclosure, only given as a non-limitative example and made in reference to attached figures, in which FIG. 1 is a schematic view of an inductive loop detection system according to an example of embodiment of the present disclosure.

### DETAILED DESCRIPTION

FIG. 1 shows an inductive loop detection system 10.

The detection system 10 is intended to detect vehicles in an area, for example a crossroad area of a railway.

The detection system 10 comprises an assembly 12 of at least one inductive detection loop embedded in the area, more particularly embedded in a road of the area. In the shown example, the detection system 10 comprises eight inductive detection loops L1 . . . L8.

The detection system 10 also comprises a detecting circuit. The detecting circuit is a resonation capacitor array 14, comprising capacitors, and connected to the assembly of inductances 12 and to a decoupling transformer 16.

The resonation capacitor array 14 comprises a main capacitor C, and preferably a plurality of additional capacitors C1 . . . C6 in parallel with the main capacitor C. Each additional capacitor C1 . . . C6 is associated with a respective switch S′1 . . . S′6. So, the global capacity depends on the combination of closed switches S′1 . . . S′6. Each capacitor C1 . . . C6 has a typical capacitance ratio of 2 in respect to the previous one, in such a way to be connected with a binary combination in order to obtain a programmable resonation capacitor.

The resonation capacitor array 14 also comprises an optional shunt R, in series with the main capacitor C.

The inductive detection loops L1 to L8 are connected in a galvanic isolated manner to the circuit by means of the transformer 16, said transformer 16 having typical loop ratio 1 to 1.

The inductive detection loops L1 . . . L8 are arranged in parallel to each other. Each inductive detection loop L1 . . . L8 is associated with a respective switch S1 . . . S8, so that the resonation capacitor array 14 can be, alternatively or in sequence, connected to each of inductive detection loops L1 . . . L8.

The resonation capacitor array 14 is energized with a Variable Frequency Square Wave signal with a typical 50% duty cycle supplied by a H-bridge controller 18, by means of an H-bridge 20.

The voltage amplitude of the driving signal is measured across the resonation capacitance C and, optionally, the current is measured at the shunt R.

The detection system 10 of the present disclosure is provided with at least one test inductor LT arranged in a test circuit 22.

A first switch 24 is arranged between the resonation capacitor array 14 and the transformer 16, and between the resonation capacitor array 14 and the test circuit 22, so the resonation capacitor array 14 can be connected to the transformer 16 or to the test circuit 22.

A second switch 26 is arranged between the transformer 16 and the assembly 12, and between the transformer 16 and the test circuit 22, so the transformer 16 can be connected to the inductive loop assembly 12 or to the test circuit 22.

When the first switch 24 connects the resonation capacitor array 14 with the test circuit 22, the resonation capacitor array 14 is directly connected with the test inductor LT.

When the first switch 24 connects the resonation capacitor array 14 with the transformer 16, and the second switch 26 connects the transformer 16 with the test circuit 22, the resonation capacitor array 14 is connected to the test inductor LT via the transformer 16.

The last two connection configurations allow the measure of the transformer 16 magnetizing inductance.

When the first switch 24 connects the resonation capacitor array 14 with the transformer 16, and the second switch 26 connects the transformer 16 with the assembly 12, the resonation capacitor array 14 is connected with the active inductive loop L1 . . . L8 via the transformer 16.

The last configuration connection allows the vehicle presence detection function through the resonation capacitor array signal comparison with the signal measured in absence of vehicles.

The test inductor LT has a defined and known inductance, so the effect on the resonance signal of the capacitor array 14 is known and may be compared with a reference signal. The comparison is indicative of the correct settings or configuration or operative status of the capacitor array 14.

Different kind of tests can be carried out on the resonant circuit and its components.

The variation of inductance is detected with a LC resonant circuit oscillation frequency change (ΔL/L=2 Δf/f).

During the installation phase the board fix the bridge power supply to obtain the voltage desired value at F₀ (central Resonant Frequency).

The measured values are:
Capacitor Voltage
H-Bridge driving Voltage
H-Bridge Power Supply Current
Loop Current (optional)
The Programmable parameters are:
H-Bridge Voltage
H-Bridge Frequency
H-Bridge Duty Cycle
Resonance Capacitor configuration (64 possible combinations with the six additional capacitors C1 . . . C6)
Loop number L1 to L8 or Test Inductor LT.
The Measured parameters for temperature compensation are:
Transformer Magnetizing Inductance
Transformer Leakage Inductance.

In a vehicle detection configuration, the loop L1 is connected to the resonation capacitor array 14. The other loops L2 . . . L8 are then connected in sequence, according to a predetermined scanning frequency.

Measurements are realized generating a variable frequency by a FPGA (Field Programmable Gate Array) device 28 and acquiring resonant circuit voltages and currents from 16 bits A/D converters after differential analog filters and FPGA digital filters and RMS calculation.

The FPGA device 28 comprises a first converter 30a acquiring current from the bridge 20, a second converter 30b acquiring voltage from the bridge 20, a third converter 30c acquiring current from the loop and a fourth converter 30d acquiring voltage from the loop.

During installation phase, the inductive loops L1 . . . L8 inductances are acquired by the detection system 10 (the loop transformer influence is removed from the measurement) in absence of vehicles. These measures are assured by an installation team surveillance, with a slow frequency scan allowing resonance frequency measure.

It should be noticed that the transformer 16 usually comprises a ferrite insulation, to decouple field from internal voltages in order to be insensitive to ground leakage and to reduce field common mode disturbances. However, this element is the most critical element influencing loop measures, due to ferrite material temperature variations.

This variation can be determined by connecting the test inductor LT to the transformer 16 via the second switch 26. For instance, this variation is determined every 15 minutes, and/or after each scan.

More particularly, the test inductor LT is used to determine any default in the resonation capacitor array. For stability purposes the test inductor LT can be realized with an air core. Since the test inductor LT has a defined and known inductance, the effect of the test inductor on a resonance signal of the resonant circuit is known and is compared with a reference signal. In case the resonance signal is different from the reference signal, the method comprises a step for recalibrating the resonant circuit. For instance, the recalibration comprises changing the capacity in the resonation capacitor array 14 by connecting the appropriate capacitors C1 . . . C6, changing the FSK frequencies, changing the H-bridge power supply voltage, changing the reference signal voltages/currents measurements or other settings or configurations.

What is claimed is:

1. A detection method for detecting vehicles within an area, using an inductive loop detection system, comprising:
at least one inductive detection loop embedded in the area; and
a resonation capacitor array configured to detect the vehicles by a change in an inductance of at least a loop determined by conductive material of the vehicles,
wherein:
the inductive loop detection system comprises at least a test inductor with a first switch for connecting the test inductor to the resonation capacitor array in place of the at least one inductive detection loop, the test inductor having a defined and known inductance, so that effect of the test inductor on a resonance signal of the resonation capacitor array is known and is compared with a reference signal; and
in case the resonance signal is different from the reference signal, the detection method comprises a recalibration for recalibrating the resonation capacitor array.

2. The detection method according to claim 1, wherein the area is a crossroad area of a railway.

3. The detection method according to claim 1, wherein the resonation capacitor array comprises a main capacitor, and a plurality of additional capacitors in parallel with the main capacitor, each additional capacitor being associated with a respective switch for connecting or disconnecting a corresponding additional capacitor with the resonation capacitor array.

4. The detection method according to claim 3, wherein the resonation capacitor array comprises a shunt, in series with the main capacitor.

5. The detection method according to claim 1, wherein the at least one inductive detection loop comprises at least two inductive loops, and wherein the at least two inductive detection loops are arranged in parallel to each other, each inductive detection loop being associated with a respective switch, so that the resonation capacitor array can be alternatively or in sequence connected to each of inductive detection loops.

6. The detection method according to claim 1, wherein the at least one inductive detection loop comprises at least two inductive loops, and wherein the at least two inductive detection loops are connected in a galvanic isolated manner to the resonation capacitor array by a transformer.

7. The detection method according to claim 6, wherein the first switch is arranged between the resonation capacitor array and the transformer, and between the resonation capacitor array and the test inductor, such that the resonation capacitor array is connected to the transformer or to the test inductor, and a second switch is arranged between the transformer and the at least two inductive detection loops, and between the transformer and the test inductor, such that the transformer is connected to the at least two inductive detection loops, or to the test inductor.

8. The detection method according to claim 1, wherein the resonation capacitor array is energized with a Variable Frequency Square Wave signal supplied by a H-bridge controller by an H-bridge.

9. The detection method according to claim 6, wherein the transformer has a loop ratio 1 to 1.
